(19) United States
(12) Patent Application Publication
(10) Pub. No.: US 2025/0233098 A1
(43) Pub. Date: Jul. 17, 2025

(54) SEMICONDUCTOR DEVICE

(71) Applicant: Taiwan Semiconductor Manufacturing Company, Ltd., Hsinchu (TW)

(72) Inventors: Yi-Huan Liao, Hsinchu (TW); Chih-Hao Chen, Taipei City (TW); Ping-Yin Hsieh, Hsinchu City (TW); Yi Wen Huang, Hsinchu City (TW); Pu Wang, Hsinchu City (TW); Li-Hui Cheng, New Taipei City (TW)

(73) Assignee: Taiwan Semiconductor Manufacturing Company, Ltd., Hsinchu (TW)

(21) Appl. No.: 18/412,581

(22) Filed: Jan. 14, 2024

(51) Int. Cl. H01L 23/00; H01L 25/065; H01L 25/16; H10B 80/00

(52) U.S. Cl. CPC H01L 24/33; H01L 24/16; H01L 24/32; H01L 24/73; H01L 25/0655; H10B 80/00; H01L 25/165; H01L 2224/16235; H01L 2224/32059; H01L 2224/32225; H01L 2224/3303; H01L 2224/33051; H01L 2224/33517; H01L 2224/33519; H01L 2224/73204; H01L 2224/73253; H01L 2225/065; H01L 2924/1434; H01L 2924/1616; H01L 2924/16251; H01L 2924/1631; H01L 2924/1632; H01L 2924/37001

(57) ABSTRACT

A semiconductor device includes a substrate, a lid, a semiconductor package and a thermal conductive bonding layer. The lid is attached to the substrate, wherein the lid has a first cavity and a second cavity extending from the first cavity to inside of the lid. The semiconductor package is disposed in the first cavity, below the second cavity and electrically connected to the substrate. The semiconductor package includes at least one semiconductor die, and the second cavity is disposed adjacent to periphery of the at least one semiconductor die in a top view of the semiconductor device. The thermal conductive bonding layer attaches the lid to the semiconductor package and extends into at least a portion of the second cavity.

### BACKGROUND

A typical problem with miniaturization of semiconductor devices is thermal dissipation during operation. A prolonged exposure of a die by operating at excessive temperatures may decrease the reliability and lifetime of the die. This problem may become severe if the die generates a lot of heat during operation. As such, improvements to thermal dissipation are still needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view illustrating a semiconductor device according to some embodiments of the present disclosure.

FIG. 2 is a simplified enlarged bottom view of a lid in FIG. 1.

FIG. 3 is a simplified top view illustrating the semiconductor device in FIG. 1, and FIG. 1 corresponds to a sectional line I-I′ in FIG. 3.

FIG. 4 is a simplified cross-sectional view corresponding to a sectional line II-II′ in FIG. 3.

FIG. 5 is a simplified cross-sectional view corresponding to a sectional line III-III′ in FIG. 3.

FIG. 6 is a simplified cross-sectional view corresponding to a sectional line IV-IV′ or V-V′ in FIG. 3.

FIG. 7 is another simplified cross-sectional view corresponding to the sectional line IV-IV′ or V-V′ in FIG. 3.

FIG. 8 is still another simplified cross-sectional view corresponding to the sectional line IV-IV′ or V-V′ in FIG. 3.

FIG. 9 is yet another simplified cross-sectional view corresponding to the sectional line IV-IV′ or V-V′ in FIG. 3.

FIG. 10 is a simplified cross-sectional view corresponding to a sectional line VI-VI′ in FIG. 3.

FIG. 11 is another simplified cross-sectional view corresponding to the sectional line VI-VI′ in FIG. 3.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Thermal interface materials (TIMs) are materials inserted between two components in order to enhance the thermal coupling between them. For example, thermal interface materials can be inserted between heat-producing devices (e.g., integrated circuits) and heat-dissipating devices (e.g., heat sinks) to enhance the thermal dissipation performance. However, poor coverage of the thermal interface material layer may occur due to volume change of the thermal interface material layer caused by significant temperature change in the post reflow process (e.g., a ball mount process), due to poor outgassing during the post reflow process, or due to inappropriate volume selection of the thermal interface material. The poorer the coverage of the thermal interface material layer, the higher the contact thermal resistance, and the lower the thermal coupling performance of the thermal interface material layer.

In the present disclosure, a lid with first and second cavities is provided to achieve better coverage of the thermal interface material layer or to reduce the number of voids generated in the thermal conductive bonding layer (or the thermal interface material layer) located between the heat-producing devices (e.g., dies) and the heat-dissipating devices (e.g., the lid).

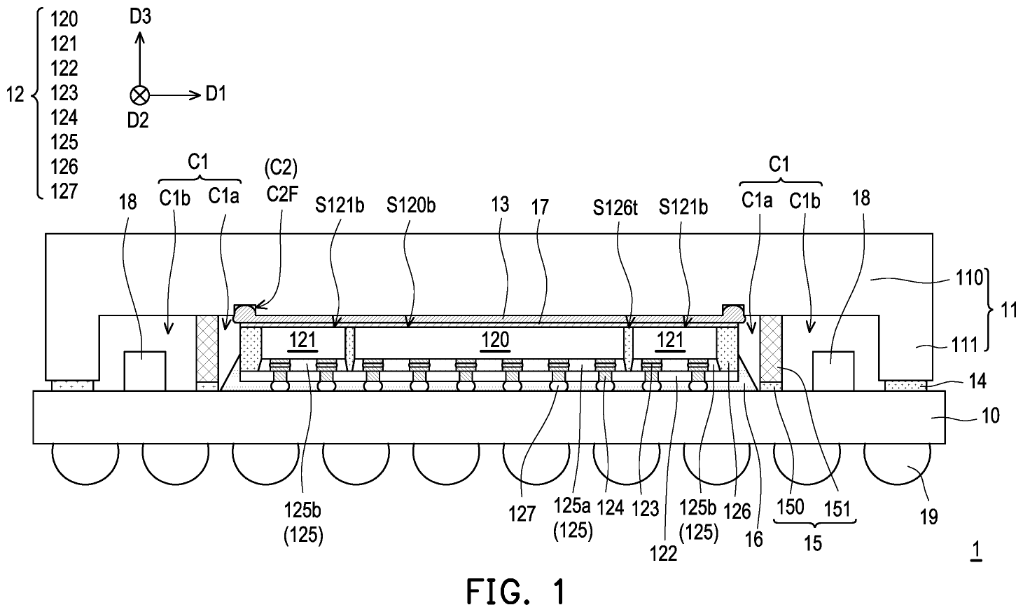

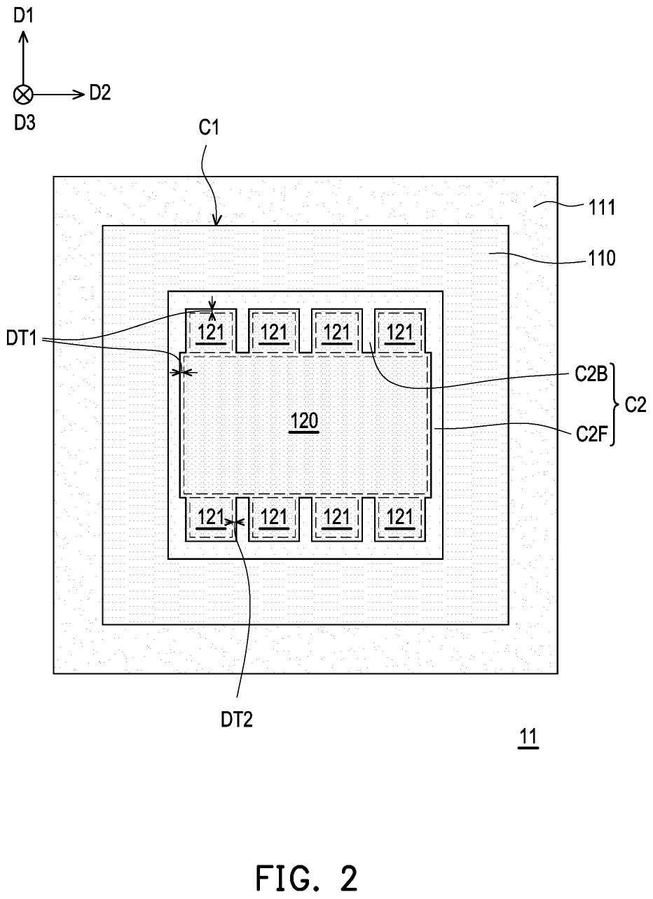

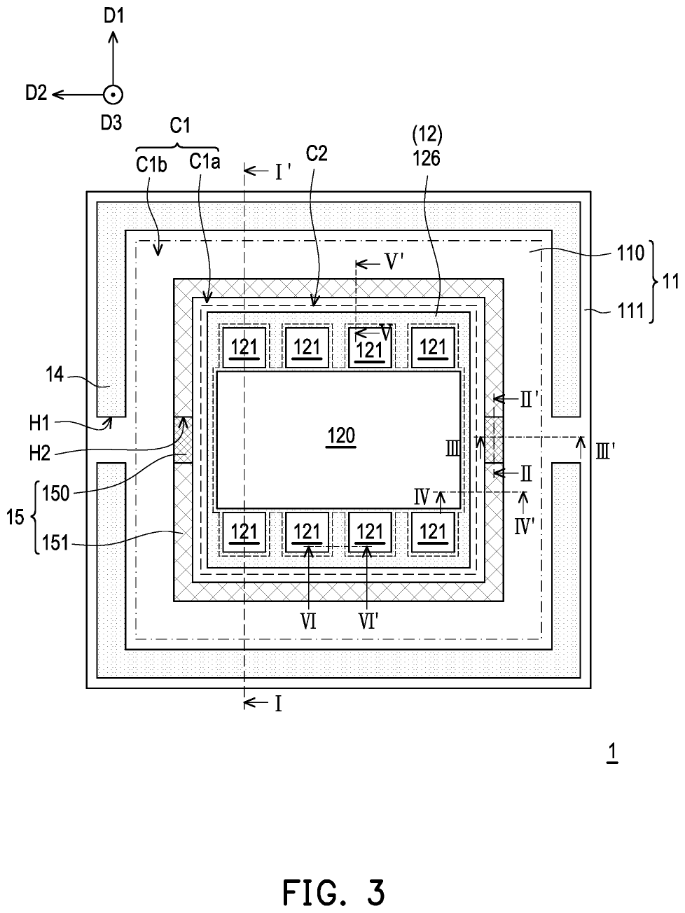

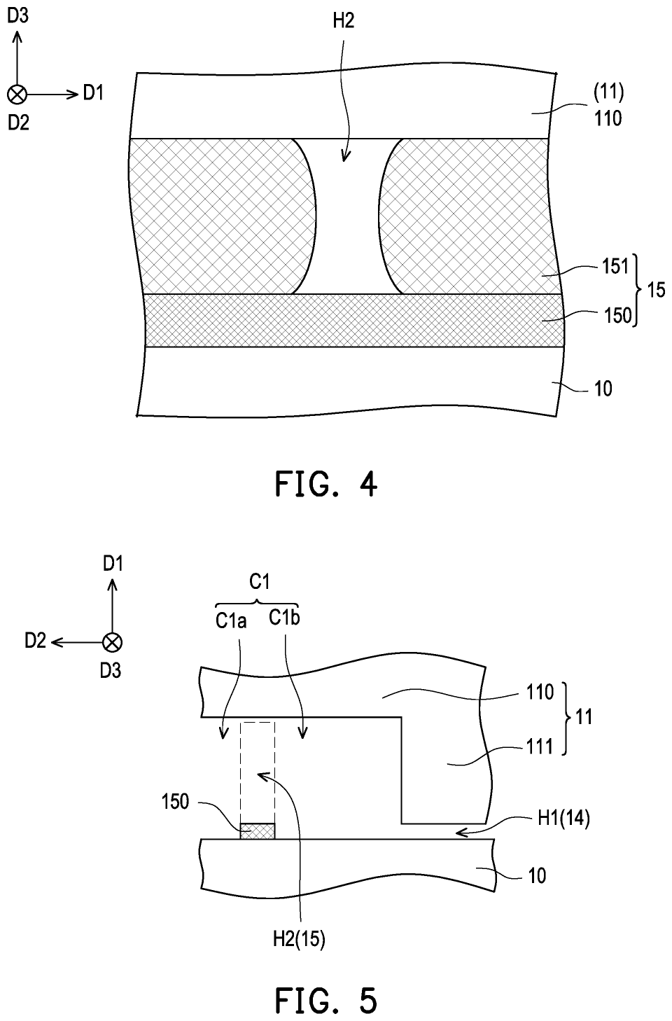

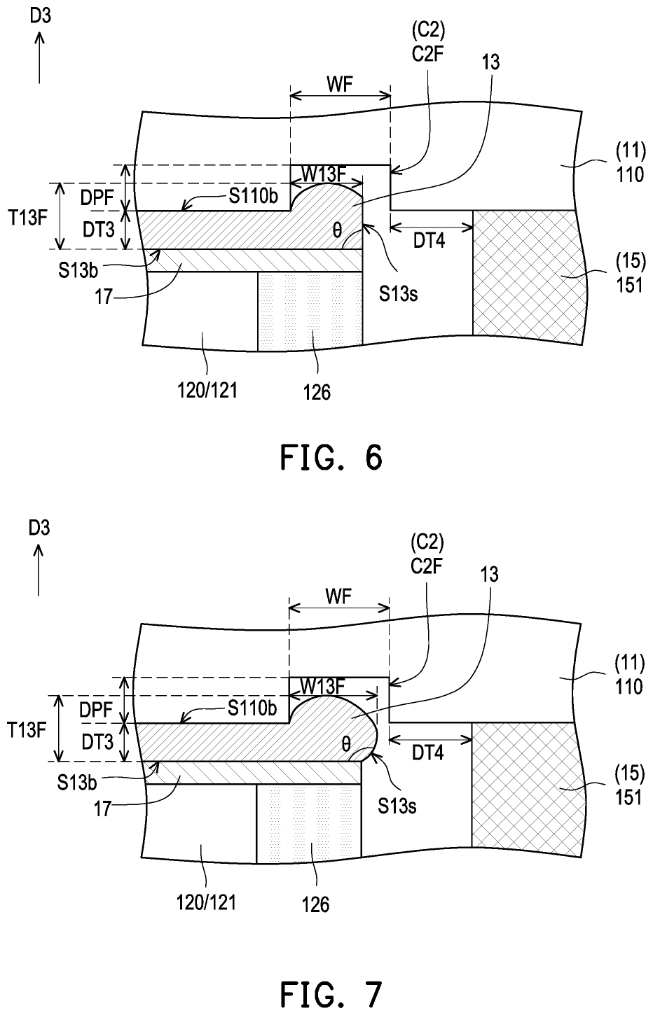

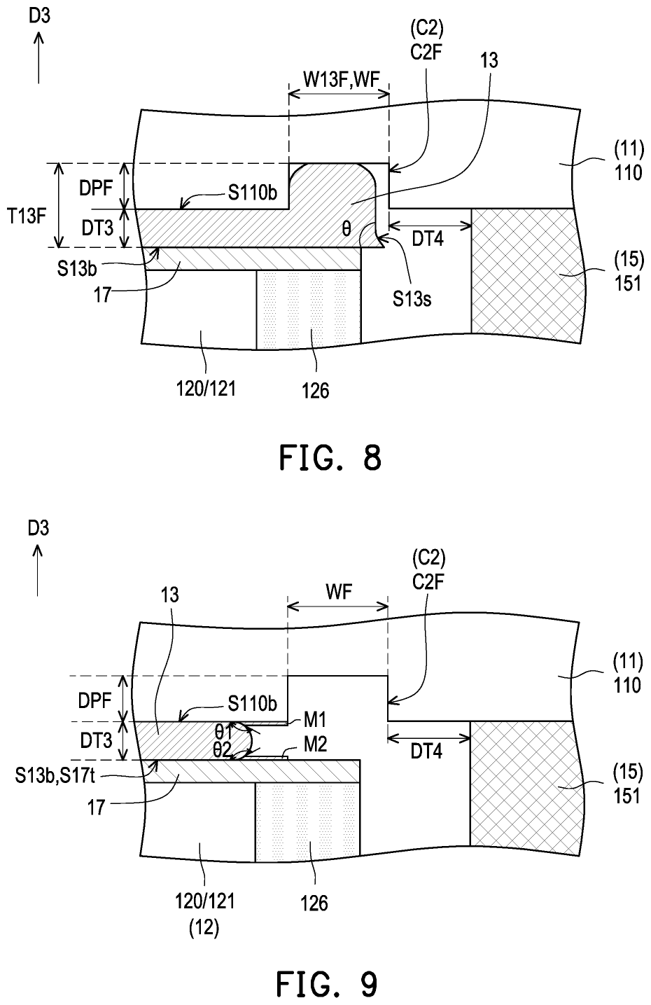

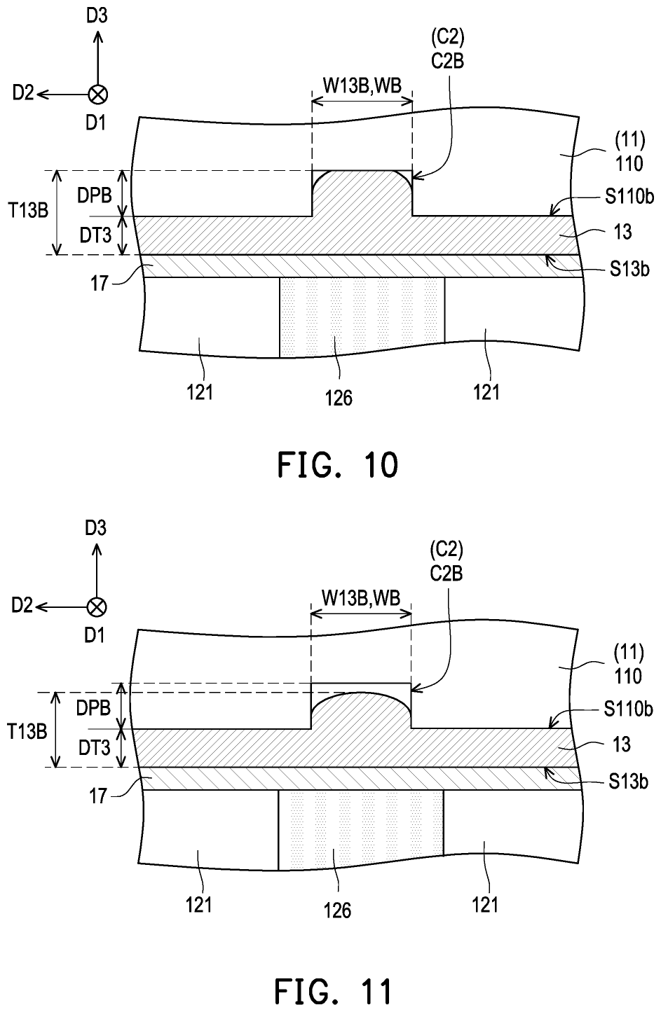

FIG. 1 is a schematic cross-sectional view illustrating a semiconductor device according to some embodiments of the present disclosure. FIG. 2 is a simplified enlarged bottom view of a lid in FIG. 1. FIG. 3 is a simplified top view illustrating the semiconductor device in FIG. 1, and FIG. 1 corresponds to a sectional line I-I′ in FIG. 3. FIG. 4 is a simplified cross-sectional view corresponding to a sectional line II-II′ in FIG. 3. FIG. 5 is a simplified cross-sectional view corresponding to a sectional line III-III′ in FIG. 3. FIG. 6 is a simplified cross-sectional view corresponding to a sectional line IV-IV′ or V-V′ in FIG. 3. FIG. 7 is another simplified cross-sectional view corresponding to the sectional line IV-IV′ or V-V′ in FIG. 3. FIG. 8 is still another simplified cross-sectional view corresponding to the sectional line IV-IV′ or V-V′ in FIG. 3. FIG. 9 is yet another simplified cross-sectional view corresponding to the sectional line IV-IV′ or V-V′ in FIG. 3. FIG. 10 is a simplified cross-sectional view corresponding to a sectional line VI-VI′ in FIG. 3. FIG. 11 is another simplified cross-sectional view corresponding to the sectional line VI-VI′ in FIG. 3.

Referring to FIG. 1, a semiconductor device 1 in accordance with some embodiments of the present disclosure is provided. The semiconductor device 1 may include a substrate 10, a lid 11, a semiconductor package 12 and a thermal conductive bonding layer 13.

The substrate 10 may include elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, the substrate 10 includes silicon on insulator (SOI) or silicon-germanium on insulator (SGOI). In some embodiments, the substrate 10 includes active components (e.g., transistors or the like) formed therein. In some embodiments, the substrate 10 includes passive components (e.g., resistors, capacitors, inductors, or the like) formed therein. In some embodiments, the substrate 10 includes a silicon wafer. In some embodiments, the substrate 10 is a package substrate or ball grid array (BGA) substrate including one or more active components, passive components, or a combination thereof. In some embodiments, the substrate 10 also includes interconnection structures and/or redistribution layers (not shown) to connect various components therein to form functional circuitry. In some embodiments, the substrate 10 may be provided for dual-side electrical connection.

The lid 11 is attached to the substrate 10 to prevent coolant (not shown) from contacting the elements thereunder. In some embodiments, the lid 11 has a first cavity C1 and a second cavity C2 extending from the first cavity C1 to inside of the lid 11. In some embodiments, the lid 11 includes a plate portion 110 and a frame portion 111 protruding from the plate portion 110 towards the substrate 10, wherein the plate portion 110 and the frame portion 111 form the first cavity C1 facing the substrate 10, and the plate portion 110 has the second cavity C2 extending from the first cavity C1 to inside of the plate portion 110. In some embodiments, the plate portion 110 extends substantially parallel to the substrate 10, and the frame portion 111 is located at edges of the plate portion 110 and extends substantially perpendicular to the substrate 10.

In some embodiments, a material of the lid 11 includes a thermally conductive material. In some embodiments, the material of the lid 11 includes metals or metal alloys, such as copper, aluminum, their alloys, the combinations thereof or the like. In some embodiments, the material of the lid 11 includes a semiconductor material such as silicon. In some embodiments, the material of the lid 11 includes polyimide, epoxy resin, acrylic resin (e.g., polymethylmethacrylate, PMMA), phenol resin, benzocyclobutene (BCB), polybenzooxazole (PBO), or any other suitable polymer-based material. In some embodiments, the material of the lid 11 includes metal diamond composites, such as Cu diamond, silver diamond, A1 diamond, or the like. In some embodiments, the lid 11 is molded, forged, 3D-printed, grown, or fabricated according to any other suitable technique. In some embodiments, multiple portions (e.g., the plate portion 110 and the frame portion 111) of the lid 11 are fabricated separately and then assembled through additional elements (e.g., screws, adhesives, or combination thereof). In some alternative embodiments, multiple portions of the lid 11 are fabricated separately and then assembled (e.g., welded) without additional elements. In other alternative embodiments, multiple portions of the lid 11 are integrally formed.

The semiconductor package 12 is disposed in the first cavity C1, below the second cavity C2 and electrically connected to the substrate 10. The semiconductor package 12 may include at least one semiconductor die, such as a first semiconductor die 110 and second semiconductor dies 111, but not limited thereto. FIG. 1 schematic shows that the semiconductor dies are arranged in a first direction D1. In some embodiments, as shown in FIG. 2, the second semiconductor dies 111 are arranged in a second direction D2. The first direction D1 and the second direction D2 are both perpendicular to a thickness direction (e.g., a third direction D3) of the substrate 10. The second direction D2 intersects the first direction D1 and is, for example, perpendicular to each other.

Each of the semiconductor dies may include a logic die, such as a central processing unit (CPU) die, a graphic processing unit (GPU) die, a micro control unit (MCU) die, an input-output (I/O) die, a baseband (BB) die, or an application processor (AP) die. In some embodiments, one or more of the semiconductor dies include a system-on-chip (SoC) dic. In some embodiments, one or more of the semiconductor dies include a memory die such as a high bandwidth memory (HBM) die. In some embodiments, the semiconductor dies may be the same type of dies or perform the same functions. In some embodiments, the semiconductor dies may be different types of dies or perform different functions. In some embodiments, the first semiconductor die 110 includes a logic die, and the second semiconductor dies 111 include memory dies. In some embodiments, the second semiconductor dies 111 are memory stacks, including multiple chips (not marked) stacked on top of each other and electrically connected by connectors (not marked). When the memory die include multiple chips, an insulating layer may be disposed between adjacent chips to protect the chips and the connectors. In some embodiments, a material of the insulating layer may include an encapsulant, a molding underfill, an epoxy, or a resin.

In some embodiments, as shown in FIG. 1, the semiconductor package 12 further includes an interposer 122, connectors 123, through vias 124, an underfill 125, an encapsulant 126 and connectors 127 in addition to the semiconductor dies.

The semiconductor dies are bonded via the connectors 123 to through vias 124 formed within the interposer 122. A material of the connectors 123 may include copper, copper alloys, or other conductive materials, and the connectors 123 may be formed by deposition, plating, or other suitable techniques. In some embodiments, the connectors 123 are prefabricated structures attached to contact pads (not marked) of the semiconductor dies. In some embodiments, the connectors 123 are solder balls, metal pillars, controlled collapse chip connection bumps, micro bumps, bumps formed via electroless nickel-electroless palladium-immersion gold technique (ENEPIG), combination thereof (e.g, a metal pillar with a solder ball attached), or the like. The interposer 122 may be made of a semiconductor material similar to those previously discussed with reference to the substrate 10, and will not be repeated here. A material of the through vias 124 may include one or more metals such as copper, titanium, tungsten, aluminum, the alloys, the combinations or the like.

The underfill 125 may be disposed between the semiconductor dies and the interposer 122 to protect the connectors 123 against thermal or physical stresses and secure the electrical connection of the semiconductor dies with the through vias 124. In some embodiments, the underfill 125 is formed by capillary underfill filling (CUF). A dispenser (not shown) may apply a filling material (not shown) along the perimeter of the semiconductor dies. In some embodiments, a heating process is performed to let the filling material penetrate in the interstices defined by the connectors 123 between the semiconductor dies and the interposer 122 by capillarity. In some embodiments, a curing process is performed to consolidate the underfill 125. In some embodiments, the underfill 125 includes underfill portions 125a and 125b spaced apart from each other, wherein the underfill portion 125a is formed between the first semiconductor die 110 and the interposer 122, and the underfill portion 125b are formed between the second semiconductor dies 111 and the interposer 122. In some alternative embodiments, a single underfill (not shown) may extend below the semiconductor dies depending on the spacing and relative positions of the semiconductor dies.

The encapsulant 126 may be formed on the interposer 122. The encapsulant 126 may cover the underfill 125 and surround the semiconductor dies. In some embodiments, the encapsulant 126 is formed by completely covering the semiconductor dies with an encapsulation material (not shown), and then performing a planarization process (e.g., a mechanical grinding process and/or a chemical mechanical polishing step) until backside surfaces S120b and S121b of the semiconductor dies are exposed. In some embodiments, the top surface S126t of the encapsulant 126 and the backside surfaces S120b and S121b of the semiconductor dies are flush or coplanar. In some embodiments, the encapsulation material may be a molding compound, a molding underfill, a resin (such as an epoxy resin), glue, or the like. In some embodiments, the encapsulation material is formed by an over-molding process. In some embodiments, the encapsulation material is formed by at least one of a compression molding process, an immersion molding process and a transfer molding process. In some embodiments, the encapsulation material may require a curing process.

The through vias 124 may be bonded to the substrate 10 via the connectors 127. A method of forming the connectors 127 and a material of the connectors 127 may be similar to those previously discussed with reference to the connectors 123, and will not be repeated here.

The thermal conductive bonding layer 13 attaches the lid 11 to the semiconductor package 12 and extends into at least a portion of the second cavity C2. The thermal conductive bonding layer 13 is configured to reduce contact thermal resistance and improve heat dissipation performance. The thermal conductive bonding layer 13 may include a thermal interface material (TIM), graphite, solder paste, nano silver paste, or other bonding material with high thermal conductivity. The thermal interface material may include a thermal grease (or thermal paste), a thermal gel, a thermal pad, a phase-change material (PCM), a phase change metal alloy, or a thermal conductive adhesive. Composition of the thermal grease may include silicon oil base, zinc oxide (ZnO), or silver (Ag), but not limited thereto. Composition of the thermal gel may include aluminum (Al), silver (Ag), silicon oil, olefin, or paraffin wax, but not limited thereto. Composition of the thermal pad may include silicone rubber, glass fiber, polyester based material, or silicone oil filled material, but not limited thereto. Composition of the phase-change material may include polyolefin resin, acrylic, aluminum (Al), aluminum oxide, or carbon nanofiber tube, but not limited thereto. Composition of the phase change metal alloy may include indium (In), alloy of indium (In) and silver (Ag), alloy of tin (Sn), silver (Ag) and copper (Cu), alloy of indium (In), tin (Sn) and bismuth (Bi), but not limited thereto. Composition of the thermal conductive adhesive may include epoxy, iron (Fe), silver (Ag), or nickel (Ni), but not limited thereto. In some embodiments, the thermal conductive bonding layer 13 is disposed on the semiconductor package 12 through coating, printing, placing, etc. In some embodiments, the thermal conductive bonding layer 13 may require curing. In some alternative embodiments, the thermal conductive bonding layer 13 may not require curing.

When the volume of the thermal conductive bonding layer 13 is inappropriate (e.g., excess) or when the volume of the thermal conductive bonding layer 13 increases due to temperature rise in subsequent processes, the second cavity C2 can accommodate the outwardly expanding thermal conductive bonding layer 13. In addition, the second cavity C2 can be used for outgassing during the subsequent processes. Specifically, the second cavity C2 is in gas communication with the first cavity C1, and the thermal conductive bonding layer 13 is disposed between the first cavity C1 and the second cavity C2. Gas residue in the interface between the thermally conductive adhesive layer 13 and the adjacent layer can be expelled to the first cavity C1 via the second cavity C2, thereby reducing the voids generated inside the thermally conductive adhesive layer 13.

In some embodiments, the second cavity C2 is disposed outside the heat-producing regions (e.g., regions where the plurality of semiconductor dies are located) of the semiconductor package 12 to maintain the thermal dissipation performance (such as thermal conduction efficiency) of the heat-producing regions. For example, the plurality of semiconductor dies are surrounded by the second cavity C2 in a top view of the semiconductor device 1. As shown in FIG. 2, in some embodiments, the second cavity C2 includes a frame portion C2F and a branch portion C2B located in and connected to the frame portion C2F. In some embodiments, the plurality of semiconductor dies (including the first semiconductor die 120 and the second semiconductor dies 121) are surrounded by the frame portion C2F, and two adjacent semiconductor dies (e.g., two adjacent second semiconductor dies 121) among the plurality of semiconductor dies are separated by the branch portion C2B in the top view of the semiconductor device 1. In some embodiments, the second cavity C2 includes a plurality of branch portions C2B, and each of the plurality of branch portions C2B is disposed between two corresponding semiconductor dies (e.g., two adjacent second semiconductor dies 121) among the plurality of semiconductor dies. In some embodiments, an extension direction of the branch portion C2B is perpendicular to an arrangement direction of the plurality of semiconductor dies. For example, an arrangement direction of the plurality of second semiconductor dies 121 is the second direction, and an extension direction of the branch portion C2B is the first direction D1.

In some embodiments, the second cavity C2 and the plurality of semiconductor dies are not overlap in the third direction D3. In some embodiments, the frame portion C2F and the branch portion C2B of the second cavity C2 are overlapped with the encapsulant 126 (see FIG. 1) of the semiconductor package 12. In some embodiments, a lateral distance DT1 between the frame portion C2F and at least one of the first semiconductor die 120 and the second semiconductor dies 121 is 0 to 0.4 mm. In some embodiments, a lateral distance DT2 between the branch portion C2B and at least one of the second semiconductor dies 121 is 0 to 0.4 mm.

In some embodiments, as shown in FIG. 10 and FIG. 11, the thermal conductive bonding layer 13 extends into the branch portion C2B of the second cavity C2. In such embodiments, a thickness T13B of the thermal conductive bonding layer 13 overlapped with the branch portion C2B is larger than a distance DT3 between a bottom surface S13b of the thermal conductive bonding layer 13 and a bottom surface S110b of the plate portion 110 and smaller than or equal to a sum of the distance DT3 and a depth DPB of the branch portion C2B. Namely, DT3<T13B< (DT3+DPB). In some embodiments, the thickness T13B of the thermal conductive bonding layer 13 overlapped with the branch portion C2B is 0.2 mm to 1 mm. In addition, a width W13B (e.g., a maximum width) of the thermal conductive bonding layer 13 overlapped with the branch portion C2B may be equal to a width WB of the branch portion C2B. In some embodiments, the width W13B of the thermal conductive bonding layer 13 overlapped with the branch portion C2B is 0.5 mm to 5 mm.

In some embodiments, as shown in FIG. 1 and FIG. 6 to FIG. 8, the thermal conductive bonding layer 13 further extends into the frame portion C2F of the second cavity C2. In such embodiments, a thickness T13F of the thermal conductive bonding layer 13 overlapped with the frame portion C2F is larger than the distance DT3 between the bottom surface S13b of the thermal conductive bonding layer 13 and the bottom surface S110b of the plate portion 110 and smaller than or equal to a sum of the distance DT3 and a depth DPF of the frame portion C2F. Namely, DT3<T13F< (DT3+DPF). In some embodiments, the thickness T13F of the thermal conductive bonding layer 13 overlapped with the frame portion C2F is 0.2 mm to 1 mm. In addition, a width W13F (e.g., a maximum width) of the thermal conductive bonding layer 13 corresponding to the frame portion C2F may be smaller than, equal to or larger than a width WF of the frame portion C2F. For example, the width W13F is larger than 0 and smaller than or equal to a sum of the width WF of the frame portion C2F and a distance DT4 between the frame portion C2F and a second adhesive 151 that bonds the plate portion 110 to the substrate 10. Namely, 0<W13F< (WF+DT4). In some embodiments, the width W13F of the thermal conductive bonding layer 13 corresponding to the frame portion C2F is 1 mm to 2 mm. In some embodiments, a contact angle θ (e.g., an angle between the bottom surface S13b of the thermal conductive bonding layer 13 and a sidewall surface S13s of the thermal conductive bonding layer 13) of the thermal conductive bonding layer 13 overlapped with the frame portion C2F is between 0° to 180° such as 30° to 150°.

In some alternative embodiments, as shown in FIG. 9, the thermal conductive bonding layer 13 is located outside the frame portion C2F. Namely, the thermal conductive bonding layer 13 is not filled into the frame portion C2F. In such embodiments, an end of the thermal conductive bonding layer 13 near the frame portion C2F has a convex shape, and contact angles θ1 and 02 of the end of the thermal conductive bonding layer 13 are 90° to 180°. In addition, the semiconductor device may further include a first intermetallic compound layer M1 disposed on a surface (e.g., the bottom surface S110b of the plate portion 110) of the lid 11 facing the semiconductor package 12 and adjacent to the thermal conductive bonding layer 13 and the frame portion C2F. Moreover, the semiconductor device may further include a second intermetallic compound layer M2 disposed on the semiconductor package 12 and adjacent to the thermal conductive bonding layer 13 and the frame portion C2F.

Specifically, the position of the end of the thermal conductive bonding layer 13 may change along with the temperature variation during the subsequent processes. For example, when the processing temperature increases, the thermal conductive bonding layer 13 expands due to heat and extends towards the edge of the semiconductor package 12; and when the processing temperature decreases, the thermal conductive bonding layer 13 contracts due to cold and extends away from the edge of the semiconductor package 12. IMC (intermetallic compound) forms at the interface between the thermal conductive bonding layer 13 and the lid 11 and/or the interface between the thermal conductive bonding layer 13 and a backside metal layer 17 located between the semiconductor package 12 and the thermal conductive bonding layer 13. As long as the surface (the bottom surface S110b of the plate portion 110 or a top surface S17t of the backside metal layer 17) was once covered by the thermal conductive bonding layer 13, even if the surface is no longer covered by the thermal conductive bonding layer 13, an IMC layer will be formed on the surface.

Note that the design parameters (e.g., shapes, widths, lengths, depths or the like) of the frame portion C2F and the branch portion C2B of the second cavity C2 in the top view or the cross-sectional view are not limited to those shown in the figures and can be changed according to needs.

Referring back to FIG. 1, in some embodiments, the semiconductor device 1 further includes a first adhesive 14 that bonds the frame portion 111 to the substrate 10. In some embodiments, the first adhesive 14 is formed on a bottom surface of the frame portion 111, and then the lid 11 on which the first adhesive 149 is formed is attached to the substrate 10. In some alternative embodiments, the first adhesive 14 is formed on the substrate 10, and then the lid 11 is attached to the first adhesive 14 on the substrate 10. The first adhesive 14 may be made of a heat resistant and waterproof material, and the first adhesive 14 may provide buffer or compensation for assembly of the lid 11. In some embodiments, a material of the first adhesive 14 includes thermocurable adhesives, photocurable adhesives, thermally conductive adhesive, thermosetting resin, waterproof adhesive, lamination adhesive or a combination thereof. In some embodiments, the material of the first adhesive 14 includes a thermally conductive adhesive. In some embodiments, the first adhesive 14 includes a metallic layer (not shown) with solder paste (not shown) deposited thereon. In some embodiments, the first adhesive 14 is epoxy, glue, or the like. In some alternative embodiments, the lid 11 is fixed on the substrate 10 through a fixing mechanism (e.g., screws), and the first adhesive 14 may be omitted. In some embodiments, the semiconductor device 1 further includes a second adhesive 15 that bonds the plate portion 110 to the substrate 10. A material and forming method of the second adhesive 15 may be similar to those previously discussed with reference to the first adhesive 14, and will not be repeated here.

In some embodiments, as shown in FIG. 1 and FIG. 3, the semiconductor package 23 and the thermal conductive bonding layer 13 are laterally surrounded by the second adhesive 15. In some embodiments, the first cavity C1 is separated by the second adhesive 15 into a first sub cavity C1a in which the semiconductor package 12 is disposed and a second sub cavity C1b located between the first sub cavity C1a and the frame portion 111. In some embodiments, the second adhesive 15 helps to keep the thermal conductive bonding layer 13 inside the first sub cavity C1a.

In some embodiments, as shown in FIG. 5, the second sub cavity C1b and external of the semiconductor device 1 are in gas communication via a first gas discharge hole H1 of the first adhesive 14, and the first sub cavity C1a and the second sub cavity C1b are in gas communication via a second gas discharge hole H2 of the second adhesive 15. In some embodiments, as shown in FIG. 3, the first gas discharge hole H1 and the second gas discharge hole H2 may be aligned in the direction D2 in the top view of the semiconductor device 1, but not limited thereto.

In some embodiments, as shown in FIG. 1, FIG. 3 and FIG. 4, the second adhesive 15 includes a first layer 150 and a second layer 151 sequentially stacked on the substrate 10. The first layer 150 may be formed together with the first adhesive 14, but not limited thereto. In some embodiments, the second gas discharge hole H2 is in the second layer 151, and thereby the second gas discharge hole H2 is higher than the first gas discharge hole H1. The first gas discharge hole H1 and the second gas discharge hole H2 helps balance the air pressure, and thereby maintaining the integrity of the second adhesive 15 or reducing the chance of the second adhesive 15 being broke by the thermal conductive bonding layer 13 due to air pressure.

Referring back to FIG. 1, in some embodiments, the semiconductor device 1 further includes an underfill 16 disposed between the semiconductor package 12 and the substrate 10 and laterally surrounded by the second adhesive 15. The underfill 16 helps to protect the connectors 127 against thermal or physical stresses and secure the electrical connection of the semiconductor dies with the substrate 10. A material and forming method of the underfill 16 may be similar to those previously discussed with reference to the underfill 125, and will not be repeated here.

In some embodiments, the semiconductor device 1 further includes a backside metal layer 17 disposed between the thermal conductive bonding layer 13 and the semiconductor package 12 to improve heat dissipation or conductivity. The backside metal layer 17 may be formed at least on the backside surface (including the backside surfaces S120b and S121b of the semiconductor dies) of the semiconductor package 12. In some embodiments, although not shown, the backside metal layer 17 is further formed on side surfaces of the semiconductor package 12 and on the underfill 16. In some embodiments, after the semiconductor package 12 and the underfill 16 are formed on the substrate 10, a shielding element (not shown; e.g., a jig or a protection tape) is disposed on the substrate 10. The shielding element has an opening that exposes the region (e.g., a region in which the semiconductor package 12 and the underfill 16 are located) where the backside metal layer 17 is to be formed. The material of the backside metal layer 17 is then formed on the shielding element and the elements (e.g., the semiconductor package 12 and the underfill 16) exposed by the opening of the shielding element through a sputtering process, a physical vapor deposition (PVD) process, a plating process, an electron beam evaporation process, or the like. In some embodiments, the backside metal layer 17 may include a stacked layer of titanium (Ti) and copper (Cu), a stacked layer of diamond-like carbon (DLC), titanium (Ti) and copper (Cu), a stacked layer of titanium (Ti), copper (Cu) and nickel (Ni), or a stacked layer of titanium (Ti), copper (Cu) and vanadium (V), but not limited thereto. In some embodiments, the backside metal layer 17 is formed from a conductive material or metal, such as Ag, Au, Ti, NiV, Al, TiN, Cu, Sn, the like, or a combination thereof. In some embodiments, the backside metal layer 17 may be formed by depositing a seed layer over the semiconductor package 12, and then electroplating the conductive material onto the seed layer.

In some embodiments, the semiconductor device 1 further includes a plurality of passive components 18 disposed on the substrate 10. In some embodiments, the plurality of passive components 18 are disposed in the second sub cavity C1b and are separated from the thermal conductive bonding layer 13 via the second adhesive 15. In some embodiments, the plurality of passive components 18 are resistors, capacitors, inductors, or the like. In some embodiments, the plurality of passive components 18 are surface mount devices (SMDs) electrically connected to the substrate 10.

In some embodiments, the semiconductor device 1 further includes connectors 19. The connectors 19 are disposed on a surface of the substrate 10 opposite to the plurality of passive components 18. A method of forming the connectors 19 and a material of the connectors 19 may be similar to those previously discussed with reference to the connectors 127, and will not be repeated here. In some embodiments, although not shown, the substrate 10 may be bonded to a printed circuit board via the connectors 19.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor device includes a substrate, a lid, a semiconductor package and a thermal conductive bonding layer. The lid is attached to the substrate, wherein the lid has a first cavity and a second cavity extending from the first cavity to inside of the lid. The semiconductor package is disposed in the first cavity, below the second cavity and electrically connected to the substrate. The semiconductor package includes at least one semiconductor die, and the second cavity is disposed adjacent to periphery of the at least one semiconductor die in a top view of the semiconductor device. The thermal conductive bonding layer attaches the lid to the semiconductor package and extends into at least a portion of the second cavity. In some embodiments, a number of the at least one die is plural, the second cavity includes a frame portion and a branch portion located in and connected to the frame portion, and wherein: the plurality of semiconductor dies are surrounded by the frame portion, and two adjacent semiconductor dies among the plurality of semiconductor dies are separated by the branch portion in the top view of the semiconductor device. In some embodiments, the frame portion is overlapped with an encapsulant of the semiconductor package. In some embodiments, two adjacent memory dies among the plurality of semiconductor dies are separated by the branch portion in the top view of the semiconductor device. In some embodiments, the thermal conductive bonding layer extends into the branch portion of the second cavity. In some embodiments, a thickness of the thermal conductive bonding layer overlapped with the branch portion is 0.2 mm to 1 mm. In some embodiments, a width of the thermal conductive bonding layer overlapped with the branch portion is 0.5 mm to 5 mm. In some embodiments, the thermal conductive bonding layer further extends into the frame portion of the second cavity. In some embodiments, a thickness of the thermal conductive bonding layer overlapped with the frame portion is 0.2 mm to 1 mm. In some embodiments, a width of the thermal conductive bonding layer corresponding to the frame portion is 1 mm to 2 mm. In some embodiments, a contact angle of the thermal conductive bonding layer overlapped with the frame portion is 30° to 150°. In some embodiments, the thermal conductive bonding layer is located outside the frame portion. In some embodiments, an end of the thermal conductive bonding layer near the frame portion has a convex shape, and contact angles of the end of the thermal conductive bonding layer are 90° to 180°. In some embodiments, the semiconductor device further includes: a first intermetallic compound layer disposed on a surface of the lid facing the semiconductor package and adjacent to the thermal conductive bonding layer and the frame portion; and a second intermetallic compound layer disposed on the semiconductor package and adjacent to the thermal conductive bonding layer and the frame portion.

According to some embodiments, a semiconductor device includes a substrate, a lid, a semiconductor package and a thermal conductive bonding layer. The lid is attached to the substrate, wherein the lid has a first cavity and a second cavity extending from the first cavity to inside of the lid. The semiconductor package is disposed in the first cavity and electrically connected to the substrate. The semiconductor package includes at least one semiconductor die, and the at least one semiconductor die is surrounded by the second cavity in a top view of the semiconductor device. The thermal conductive bonding layer attaches the lid to the semiconductor package and extends into at least a portion of the second cavity. In some embodiments, the at least one semiconductor die includes a first semiconductor die and second semiconductor dies, and the second cavity includes a frame portion and a branch portion located in and connected to the frame portion, and wherein: the first semiconductor die and the second semiconductor dies are surrounded by the frame portion, and the second semiconductor dies are separated by the branch portion in the top view of the semiconductor device, a lateral distance between the frame portion and at least one of the first semiconductor die and the second semiconductor dies is 0 to 0.4 mm, and a lateral distance between the branch portion and at least one of the second semiconductor dies is 0 to 0.4 mm.

According to some embodiments, a semiconductor device includes a substrate, a lid, a first adhesive, a second adhesive, a semiconductor package and a thermal conductive bonding layer. The lid includes a plate portion and an frame portion protruding from the plate portion towards the substrate, wherein the plate portion and the frame portion form a first cavity facing the substrate, and the plate portion has a second cavity extending from the first cavity to inside of the plate portion. The first adhesive bonds the frame portion to the substrate. The second adhesive bonds the plate portion to the substrate. The semiconductor package is disposed in the first cavity, below the second cavity, electrically connected to the substrate and laterally surrounded by the second adhesive. The thermal conductive bonding layer is disposed on the semiconductor package, laterally surrounded by the second adhesive and extends into at least a portion of the second cavity. In some embodiments, the semiconductor device further includes an underfill disposed between the semiconductor package and the substrate and laterally surrounded by the second adhesive. In some embodiments, the first cavity is separated by the second adhesive into a first sub cavity in which the semiconductor package is disposed and a second sub cavity located between the first sub cavity and the frame portion, the second sub cavity and external of the semiconductor device are in gas communication via a first gas discharge hole of the first adhesive, and the first sub cavity and the second sub cavity are in gas communication via a second gas discharge hole of the second adhesive. In some embodiments, the second gas discharge hole is higher than the first gas discharge hole.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a lid attached to the substrate, wherein the lid has a first cavity and a second cavity extending from the first cavity to inside of the lid;
a semiconductor package disposed in the first cavity, below the second cavity and electrically connected to the substrate, wherein the semiconductor package comprises at least one semiconductor die, and the second cavity is disposed adjacent to periphery of at least one semiconductor die in a top view of the semiconductor device; and
a thermal conductive bonding layer attaching the lid to the semiconductor package and extending into at least a portion of the second cavity.

2. The semiconductor device as claimed in claim 1, wherein a number of the at least one die is plural, the second cavity comprises a frame portion and a branch portion located in and connected to the frame portion, and wherein:
the plurality of semiconductor dies are surrounded by the frame portion, and two adjacent semiconductor dies among the plurality of semiconductor dies are separated by the branch portion in the top view of the semiconductor device.

3. The semiconductor device as claimed in claim 2, wherein the frame portion and the branch portion are overlapped with an encapsulant of the semiconductor package.

4. The semiconductor device as claimed in claim 2, wherein two adjacent memory dies among the plurality of semiconductor dies are separated by the branch portion in the top view of the semiconductor device.

5. The semiconductor device as claimed in claim 2, wherein the thermal conductive bonding layer extends into the branch portion of the second cavity.

6. The semiconductor device as claimed in claim 5, wherein a thickness of the thermal conductive bonding layer overlapped with the branch portion is 0.2 mm to 1 mm.

7. The semiconductor device as claimed in claim 5, wherein a width of the thermal conductive bonding layer overlapped with the branch portion is 0.5 mm to 5 mm.

8. The semiconductor device as claimed in claim 5, wherein the thermal conductive bonding layer further extends into the frame portion of the second cavity.

9. The semiconductor device as claimed in claim 8, wherein a thickness of the thermal conductive bonding layer overlapped with the frame portion is 0.2 mm to 1 mm.

10. The semiconductor device as claimed in claim 8, wherein a width of the thermal conductive bonding layer corresponding to the frame portion is 1 mm to 2 mm.

11. The semiconductor device as claimed in claim 8, wherein a contact angle of the thermal conductive bonding layer overlapped with the frame portion is 30° to 150°.

12. The semiconductor device as claimed in claim 5, wherein the thermal conductive bonding layer is located outside the frame portion.

13. The semiconductor device as claimed in claim 12, wherein an end of the thermal conductive bonding layer near the frame portion has a convex shape, and contact angles of the end of the thermal conductive bonding layer are 90° to 180°.

14. The semiconductor device as claimed in claim 12, further comprising:
a first intermetallic compound layer disposed on a surface of the lid facing the semiconductor package and adjacent to the thermal conductive bonding layer and the frame portion; and
a second intermetallic compound layer disposed on the semiconductor package and adjacent to the thermal conductive bonding layer and the frame portion.

15. A semiconductor device, comprising:
a substrate;
a lid attached to the substrate, wherein the lid has a first cavity and a second cavity extending from the first cavity to inside of the lid;
a semiconductor package disposed in the first cavity and electrically connected to the substrate, wherein the semiconductor package comprises at least one semiconductor die, and the at least one semiconductor die is surrounded by the second cavity in a top view of the semiconductor device; and
a thermal conductive bonding layer attaching the lid to the semiconductor package and extending into at least a portion of the second cavity.

16. The semiconductor device as claimed in claim 15, wherein the at least one semiconductor die comprises a first semiconductor die and second semiconductor dies, and the second cavity comprises a frame portion and a branch portion located in and connected to the frame portion, and wherein:
the first semiconductor die and the second semiconductor dies are surrounded by the frame portion, and the second semiconductor dies are separated by the branch portion in the top view of the semiconductor device,
a lateral distance between the frame portion and at least one of the first semiconductor die and the second semiconductor dies is 0 to 0.4 mm, and
a lateral distance between the branch portion and at least one of the second semiconductor dies is 0 to 0.4 mm.

17. A semiconductor device, comprising:
a substrate;
a lid comprising a plate portion and an frame portion protruding from the plate portion towards the substrate, wherein the plate portion and the frame portion form a first cavity facing the substrate, and the plate portion has a second cavity extending from the first cavity to inside of the plate portion;
a first adhesive bonding the frame portion to the substrate;
a second adhesive bonding the plate portion to the substrate;
a semiconductor package disposed in the first cavity, below the second cavity, electrically connected to the substrate and laterally surrounded by the second adhesive; and
a thermal conductive bonding layer disposed on the semiconductor package, laterally surrounded by the second adhesive and extending into at least a portion of the second cavity.

18. The semiconductor device as claimed in claim 17, further comprising:
an underfill disposed between the semiconductor package and the substrate and laterally surrounded by the second adhesive.

19. The semiconductor device as claimed in claim 17, wherein:
the first cavity is separated by the second adhesive into a first sub cavity in which the semiconductor package is disposed and a second sub cavity located between the first sub cavity and the frame portion,
the second sub cavity and external of the semiconductor device are in gas communication via a first gas discharge hole of the first adhesive, and
the first sub cavity and the second sub cavity are in gas communication via a second gas discharge hole of the second adhesive.

20. The semiconductor device as claimed in claim 19, wherein the second gas discharge hole is higher than the first gas discharge hole.
